(19) United States
(12) Patent Application Publication
(10) Pub. No.: US 2025/0311163 A1
(43) Pub. Date: Oct. 2, 2025

(54) WIRELESS POWER TRANSMISSION DEVICE

(71) Applicant: Lite-On Technology Corporation, Taipei (TW)

(72) Inventors: Li-Yuan Hsu, Taipei (TW); Yu Wei Chiu, Taipei (TW)

(73) Assignee: Lite-On Technology Corporation, Taipei (TW)

(21) Appl. No.: 18/931,060

(22) Filed: Oct. 30, 2024

Related U.S. Application Data
(60) Provisional application No. 63/569,743, filed on Mar. 26, 2024.

(30) Foreign Application Priority Data
Sep. 5, 2024 (CN) 202411242950.5

(51) Int. Cl. H05K 7/20; B82Y 30/00; H02J 50/00; H02J 50/10

(52) U.S. Cl. CPC H05K 7/2039; B82Y 30/00; H02J 50/005; H02J 50/10

(57) ABSTRACT

A wireless power transmission device including a heat dissipation casing, an energy transmission module, a first heat dissipation colloid and a second heat dissipation colloid is provided. The energy transmission module is disposed in the heat dissipation casing and includes a coil and magnetic isolation assembly. The magnetic isolation assembly is disposed between the coil and the heat dissipation casing. The first heat dissipation colloid is disposed between the coil and the magnetic isolation assembly to make thermocouple of the coil with the magnetic isolation assembly. The second heat dissipation colloid is disposed between the magnetic isolation assembly and the heat dissipation casing to make thermocouple of the magnetic isolation assembly with the heat dissipation casing, wherein the heat generating during an operation of the coil is transmitted to the heat dissipation casing sequentially through the first dissipation colloid, the magnetic isolation assembly and the second dissipation colloid.

### CROSS-REFERENCE TO RELATED APPLICATION

This application claims the priority benefit of U.S. provisional application Ser. No. 63/569,743, filed on Mar. 26, 2024 and China application serial no. 202411242950.5, filed on Sep. 5, 2024. The entirety of each of the above-mentioned patent applications is hereby incorporated by reference herein and made a part of this specification.

### BACKGROUND

### Technical Field

The invention relates to a wireless power transmission device, and particularly relates to a wireless power transmission device with a good heat dissipation effect.

### Description of Related Art

Along with continues improvement of performance of wireless power transmission devices, heat generated by the wireless power transmission devices also increases. Therefore, how to make the wireless power transmission devices to have a good heat dissipation effect is a topic that needs to be discussed in this field.

### SUMMARY

The invention is directed to a wireless power transmission device, which has a good heat dissipation effect.

The invention provides a wireless power transmission device including a heat dissipation casing, an energy transmission module, a first heat dissipation colloid and a second heat dissipation colloid. The energy transmission module is disposed in the heat dissipation casing and includes a coil and a magnetic isolation assembly. The magnetic isolation assembly is disposed between the coil and the heat dissipation casing. The first heat dissipation colloid is disposed between the coil and the magnetic isolation assembly to make thermocouple of the coil with the magnetic isolation assembly. The second heat dissipation colloid is disposed between the magnetic isolation assembly and the heat dissipation casing to make thermocouple of the magnetic isolation assembly with the heat dissipation casing, where heat generated during an operation of the coil is sequentially transmitted to the heat dissipation casing through the first dissipation colloid, the magnetic isolation assembly and the second dissipation colloid.

In an embodiment of the invention, the wireless power transmission device further includes a blocking structure, where the heat dissipation casing includes a first region corresponding to the energy transmission module and a retaining wall located next to the first region. The first region includes a groove, the second heat dissipation colloid is located in the first region and fills a part of the groove, the retaining wall includes an opening corresponding to the groove, and the blocking structure is disposed in the opening.

In an embodiment of the invention, the energy transmission module includes a wire extending from the coil, the blocking structure includes a notch recessed from an edge, and the wire is located in the groove and extends out of the first region through the notch and the opening.

In an embodiment of the invention, the blocking structure includes a first layer structure and a second layer structure attached to the first layer structure. The first layer structure includes the notch, and the second layer structure includes a torn region defined by a perforated line, the torn region corresponds to the notch, a strength of the second layer structure is less than a strength of the first layer structure, and the wire passes through the torn region and the notch.

In an embodiment of the invention, the wireless power transmission device further includes a circuit board, where the heat dissipation casing includes a second region, the retaining wall is located between the first region and the second region, the circuit board is located in the second region, and the wire extends to the circuit board through the notch and the opening.

In an embodiment of the invention, the heat dissipation casing includes a liquid cooling pipeline, the heat dissipation casing includes a first region corresponding to the energy transmission module, and an extension direction of the liquid cooling pipeline in the first region corresponds to an extending direction of the coil.

In an embodiment of the invention, the heat dissipation casing includes a plurality of fins located in the liquid cooling pipeline, and an extending direction of the plurality of fins in the first region corresponds to the extending direction of the coil.

In an embodiment of the invention, the wireless power transmission device further includes a circuit board, where the heat dissipation casing includes a second region, the circuit board is located in the second region, and the liquid cooling pipeline extends from the second region to the first region.

In an embodiment of the invention, the energy transmission module further includes a coil bracket disposed between the coil and the magnetic isolation assembly, and the coil bracket includes a through slot with a shape corresponding to the coil, and the first heat dissipation colloid is filled in the through slot.

In an embodiment of the invention, the energy transmission module further includes a magnetic isolation assembly bracket disposed between the magnetic isolation assembly and the heat dissipation casing, and the magnetic isolation assembly bracket includes a plurality of through holes, and the second heat dissipation colloid is filled in the plurality of through holes.

In an embodiment of the invention, the energy transmission module includes an inner cover, the coil and the magnetic isolation assembly are located between the inner cover and the heat dissipation casing, and the inner cover is fixed to the heat dissipation casing to fix the coil and the magnetic isolation assembly in the heat dissipation casing.

In an embodiment of the invention, the wireless power transmission device further includes a circuit board and an outer cover, where the heat dissipation casing includes a first region and a second region, the energy transmission module is located in the first region, the circuit board is located in the second region, and the energy transmission module and the circuit board are located between the outer cover and the heat dissipation casing, and the outer cover is fixed to the heat dissipation casing.

According to the above descriptions, the wireless power transmission device of the invention includes the heat dissipation casing, the energy transmission module, the first heat dissipation colloid and the second heat dissipation colloid. The wireless power transmission device is sequentially arranged on one side of the coil of the energy transmission module through the first heat dissipation colloid, the magnetic isolation assembly of the energy transmission module, the second heat dissipation colloid, and the heat dissipation casing, so that the heat of the coil is transmitted to the heat dissipation casing through the first heat dissipation colloid, the magnetic isolation assembly and the second heat dissipation colloid. In this way, the heat of the coil of the wireless power transmission device may be effectively dissipated, and the wireless power transmission device has good heat dissipation effect.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a wireless power transmission device according to an embodiment of the invention.

FIG. 2 is an exploded view of the wireless power transmission device of FIG. 1.

FIG. 3 is a cross-sectional view of the wireless power transmission device of FIG. 1 along a line A-A.

FIG. 4 is a partial enlarged view of a region A of a heat dissipation casing of FIG. 2.

FIG. 5 shows a second heat dissipation colloid filled in the heat dissipation casing of FIG. 4.

FIG. 6 is a three-dimensional view of a blocking structure of FIG. 4.

FIG. 7 is an exploded view of the blocking structure of FIG. 6.

FIG. 8 is a schematic diagram of a first heat dissipation colloid of FIG. 3 filling in a coil bracket.

FIG. 9 is a schematic diagram of the second heat dissipation colloid of FIG. 3 filling in a heat dissipation casing and a magnetic isolation assembly bracket.

FIG. 10 is a schematic diagram of a heat dissipation casing of FIG. 2 from another viewing angle.

### DESCRIPTION OF THE EMBODIMENTS

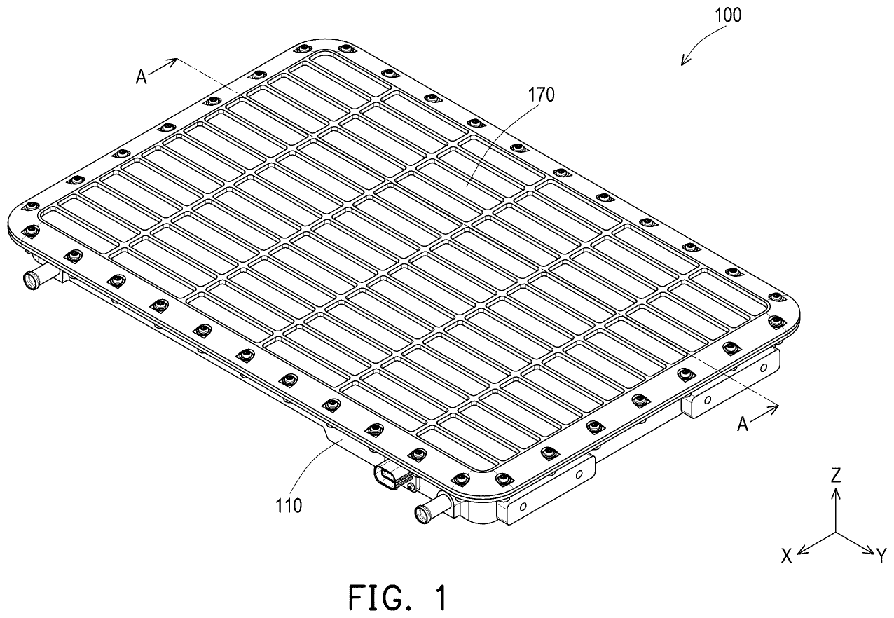

FIG. 1 is a schematic diagram of a wireless power transmission device according to an embodiment of the invention. Referring to FIG. 1, a wireless power transmission device 100 of the embodiment is suitable for applying to electric vehicles and may be used as a receiving end of wireless power transmission, but the invention is not limited thereto. A structure of the wireless power transmission device 100 of the embodiment will be described in detail below.

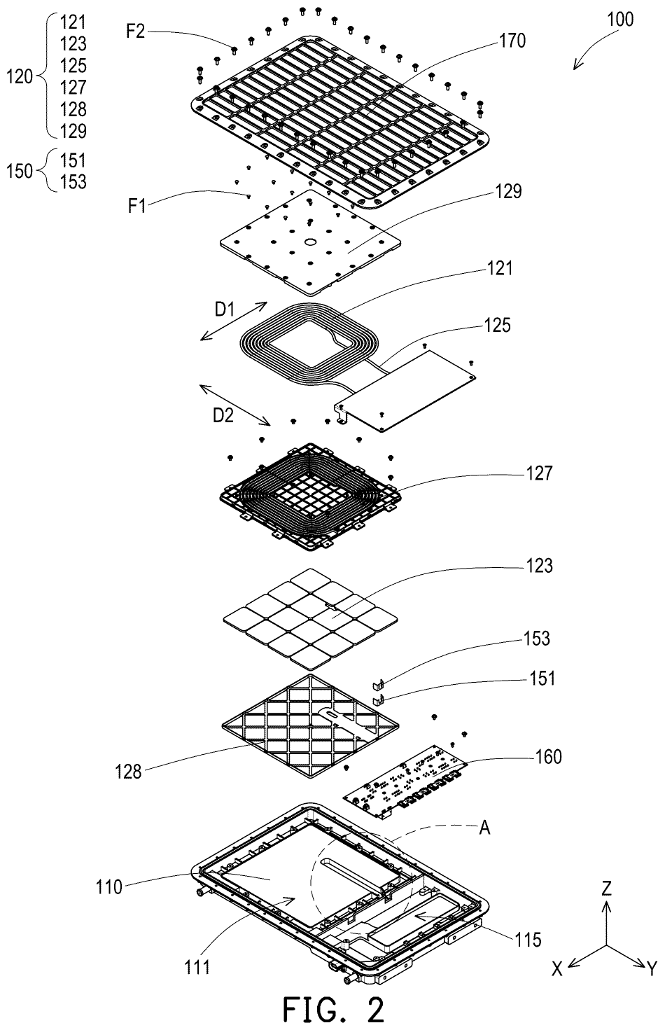

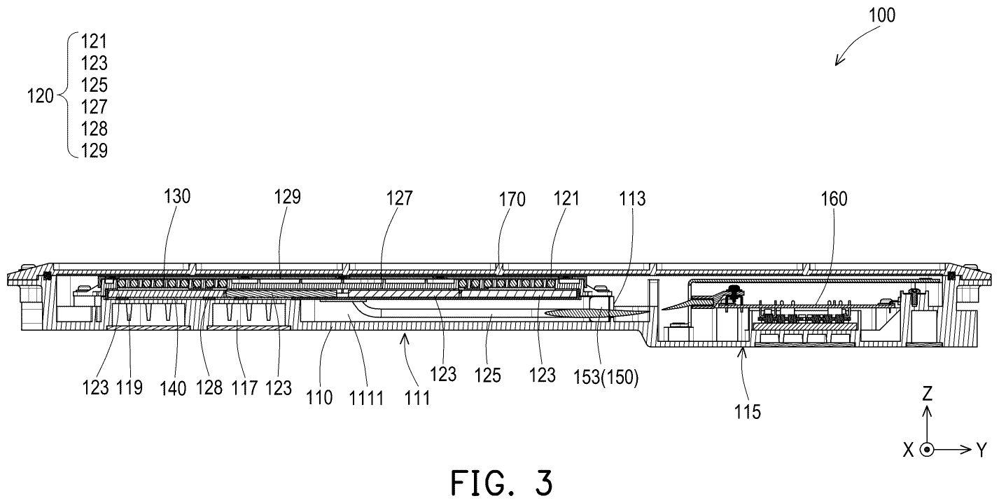

FIG. 2 is an exploded view of the wireless power transmission device of FIG. 1. FIG. 3 is a cross-sectional view of the wireless power transmission device of FIG. 1 along a line A-A. In order to clearly illustrate a heat dissipation casing 110 and a coil bracket 127, a first heat dissipation colloid 130 and a second heat dissipation colloid 140 are not shown in FIG. 2.

Referring to FIG. 2 and FIG. 3, the wireless power transmission device 100 includes a heat dissipation casing 110, an energy transmission module 120, a first heat dissipation colloid 130 (FIG. 3) and a second heat dissipation colloid 140 (FIG. 3). The energy transmission module 120 is disposed in the heat dissipation casing 110 and includes a coil 121 and a magnetic isolation assembly 123. The magnetic isolation assembly 123 is disposed between the coil 121 and the heat dissipation casing 110. The first heat dissipation colloid 130 is disposed between the coil 121 and the magnetic isolation assembly 123 as shown in FIG. 3 to make thermocouple of the coil 121 with the magnetic isolation assembly 123. The second heat dissipation colloid 140 is disposed between the magnetic isolation assembly 123 and the heat dissipation casing 110 as shown in FIG. 3 to make thermocouple of the magnetic isolation assembly 123 with the heat dissipation casing 110. Accordingly, heat energy generated by the coil 121 during operation is sequentially transmitted to the heat dissipation casing 110 through the first heat dissipation colloid 130, the magnetic isolation assembly 123 and the second heat dissipation colloid 140, so that the heat of the coil 121 may be effectively dissipated, and the wireless power transmission device 100 has good heat dissipation effect.

In the embodiment, the wireless power transmission device 100 changes a direction of magnetic field lines through the magnetic isolation assembly 123 to limit the magnetic field lines between a transmitting end and a receiving end. In addition, in the embodiment, the magnetic isolation assemblies 123 are, for example, ferrite magnetic sheets, and a number thereof is sixteen, but the type and quantity of the magnetic isolation assemblies 123 are not limited thereto.

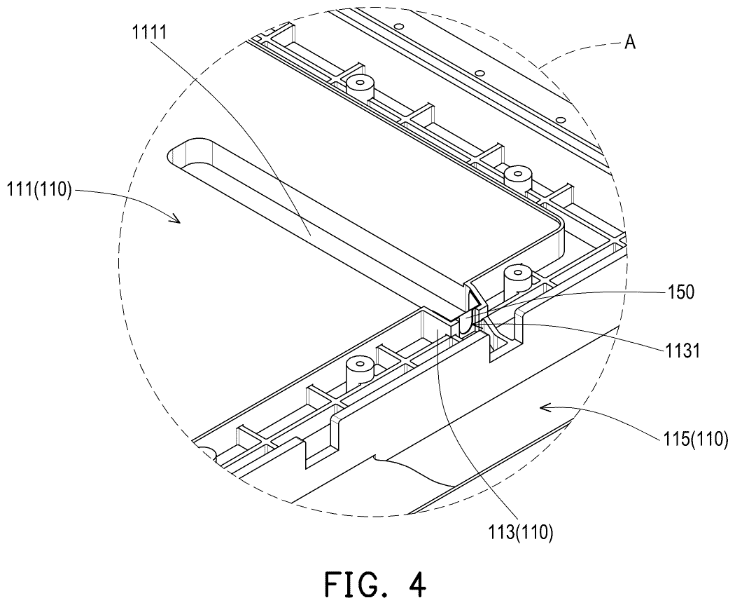

FIG. 4 is a partial enlarged view of a region A of the heat dissipation casing of FIG. 2. Referring to FIG. 2 to FIG. 4, the heat dissipation casing 110 includes a first region 111 corresponding to the energy transmission module 120, a retaining wall 113 located next to the first region 111, and a second region 115 located on another side of the retaining wall 113. The first region 111 includes a groove 1111. The retaining wall 113 is located between the first region 111 and the second region 115 and includes an opening 1131 corresponding to the groove 1111. The coil 121 is disposed in the first region 111 as shown in FIG. 3.

Referring to FIG. 2 and FIG. 3, the wireless power transmission device 100 further includes a circuit board 160. The circuit board 160 is located in the second region 115, and the circuit board 160 is electrically connected to the coil 121. To be specific, the energy transmission module 120 includes a wire 125 extending from the coil 121. The wire 125 is located in the groove 1111 as shown in FIG. 3, and extends out of the first region 111 through the opening 1131 of the retaining wall 113 as shown in FIG. 4, and is connected to the circuit board 160 located in the second region 115, so that the coil 121 is electrically connected to the circuit board 160 through the wire 125.

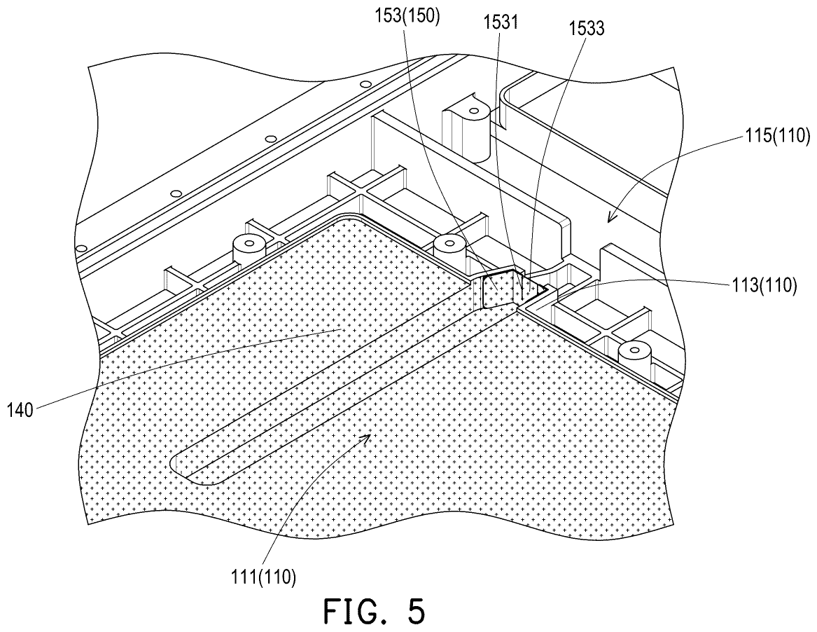

FIG. 5 shows the second heat dissipation colloid filled in the heat dissipation casing of FIG. 4. Referring to FIG. 4 and FIG. 5, the wireless power transmission device 100 further includes a blocking structure 150. The blocking structure 150 is disposed in the opening 1131 of the retaining wall 113 of the heat dissipation casing 110 as shown in FIG. 4.

Specifically, during an assembling process, when the second heat dissipation colloid 140 is filled into the heat dissipation casing 110, the second heat dissipation colloid 140 is located in the first region 111 as shown in FIG. 5 and fills in a part of the groove 1111. Since the second heat dissipation colloid 140 has fluidity, in order to prevent the second heat dissipation colloid 140 from flowing out of the heat dissipation casing 110 from the opening 1131 next to the groove 1111 to cause waste, in the embodiment, the wireless power transmission device 100 blocks the second heat dissipation colloid 140 located in the first region 111 from flowing out by using the blocking structure 150. Accordingly, the wireless power transmission device 100 may effectively save a usage amount of the second heat dissipation colloid 140 through the blocking structure 150, and may improve convenience of assembling. The structure of the blocking structure 150 is described in detail below.

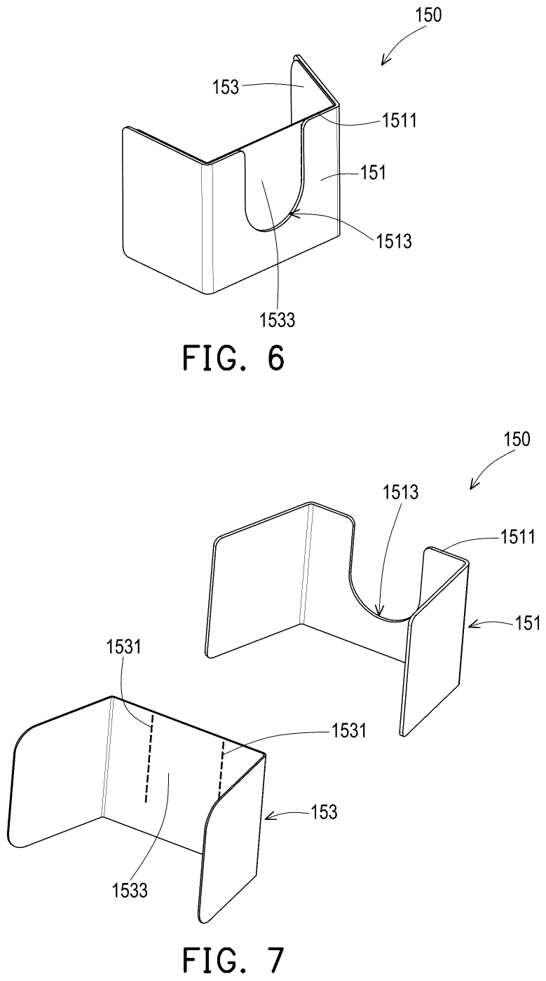

FIG. 6 is a three-dimensional view of the blocking structure of FIG. 4. FIG. 7 is an exploded view of the blocking structure of FIG. 6. Referring to FIG. 6 and FIG. 7, the blocking structure 150 of the embodiment includes a first layer structure 151 attached to the retaining wall 113 and a second layer structure 153 attached to the first layer structure 151. The first layer structure 151 includes a notch 1513 recessed from an edge 1511. When the first layer structure 151 is attached to the retaining wall 113, the notch 1513 corresponds to the opening 1131 of the retaining wall 113 (FIG. 4). The second layer structure 153 includes a torn region 1533 defined by a perforated line 1531. When the second layer structure 153 is attached to the first layer structure 151, the torn region 1533 corresponds to the notch 1513. In the embodiment, a strength of the second layer structure 153 is smaller than a strength of the first layer structure 151.

Accordingly, the first layer structure 151 may serve as a support structure of the blocking structure 150, and when the wire 125 is located in the groove 1111 as mentioned above, the wire 125 may pass through the torn region 1533 by destroying the perforated line 1531 to extend to the circuit board 160 located outside the first region 111 through the notch 1513 of the blocking structure 150 and the opening 1131 of the retaining wall 113. After the wire 125 passes through the torn region 1533, the notch 1513 and the opening 1131, the wireless power transmission device 100 blocks the notch 1513 through the wire 125 to prevent the second heat dissipation colloid 140 from flowing out.

In the embodiment, a width of the notch 1513 corresponds to a diameter length of the wire 125 (FIG. 2), but the invention is not limited thereto. In addition, in the embodiment, the first layer structure 151 is, for example, a PET plastic sheet with back glue, and the second layer structure 153 is, for example, a PC film with back glue, but materials of the first layer structure 151 and the second layer structure 153 are not limited thereto.

The structure of the energy transmission module 120 of the embodiment is described in detail below.

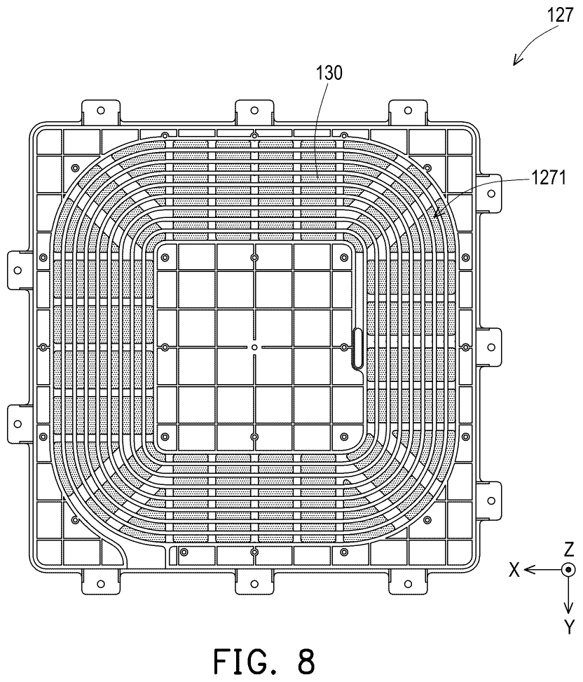

FIG. 8 is a schematic diagram of the first heat dissipation colloid of FIG. 3 filling in the coil bracket. In order to clearly illustrate the first heat dissipation colloid 130 and the coil bracket 127, FIG. 8 only shows the first heat dissipation colloid 130 and the coil bracket 127.

Referring to FIG. 2, FIG. 3 and FIG. 8, the energy transmission module 120 of the embodiment further includes a coil bracket 127, the coil 121 is disposed on the coil bracket 127 as shown in FIG. 3, and the coil bracket 127 is disposed between the coil 121 and the magnetic isolation assembly 123. In detail, the coil bracket 127 includes a through slot 1271 with a shape corresponding to the coil 121. After the coil 121 is placed in the through slot 1271 of the coil bracket 127, an assembler may dispose the first heat dissipation colloid 130 on a side of the coil 121 and the coil bracket 127 relative to the magnetic isolation assembly 123, and fill the same in the through slot 1271 (FIG. 8).

In this way, the first heat dissipation colloid 130 is located between the coil 121 and the magnetic isolation assembly 123 as shown in FIG. 3, and the heat generated by the coil 121 may be transmitted to the magnetic isolation assembly 123 through the first heat dissipation colloid 130.

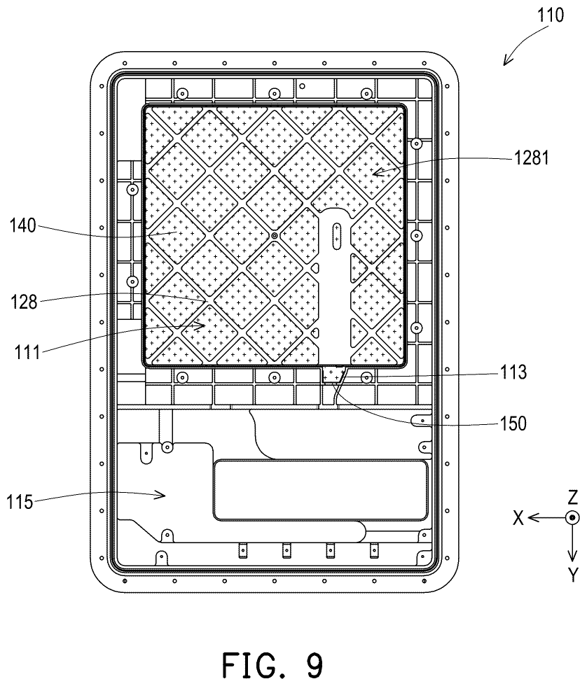

FIG. 9 is a schematic diagram of the second heat dissipation colloid of FIG. 3 filling in the heat dissipation casing and a magnetic isolation assembly bracket. In order to clearly illustrate the second heat dissipation colloid 140 and the magnetic isolation assembly bracket 128, FIG. 9 only shows the heat dissipation casing 110, the second heat dissipation colloid 140 and the magnetic isolation assembly bracket 128.

Referring to FIG. 2, FIG. 3 and FIG. 9, the energy transmission module 120 of the embodiment further includes the magnetic isolation assembly bracket 128, the magnetic isolation assembly 123 is disposed on the magnetic isolation assembly bracket 128 and the magnetic isolation assembly bracket 128 is disposed between the magnetic isolation assembly 123 and the heat dissipation casing 110 as shown in FIG. 3. The magnetic isolation assembly bracket 128 includes a plurality of through holes 1281 (FIG. 9). After the second heat dissipation colloid 140 is disposed in the first region 111 of the heat dissipation casing 110 as described above, the magnetic isolation assembly bracket 128 may be correspondingly disposed in the first region 111 of the heat dissipation casing 110. Accordingly, the second heat dissipation colloid 140 is filled in the plurality of through holes 1281 and is located between the magnetic isolation assembly 123 and the heat dissipation casing 110, so that the heat received by the magnetic isolation assembly 123 may be transmitted to the heat dissipation casing 110 through the second heat dissipation colloid 140.

Referring to FIG. 2 and FIG. 3, the energy transmission module 120 further includes an inner cover 129. The coil 121 and the magnetic isolation assembly 123 are located between the inner cover 129 and the heat dissipation casing 110. The inner cover 129 is fixed to the heat dissipation casing 110 through fasteners F1 (for example, screws), so as to fix the coil 121 and the magnetic isolation assembly 123 in the heat dissipation casing 110.

The internal heat dissipation structure of the heat dissipation casing 110 is described in detail below.

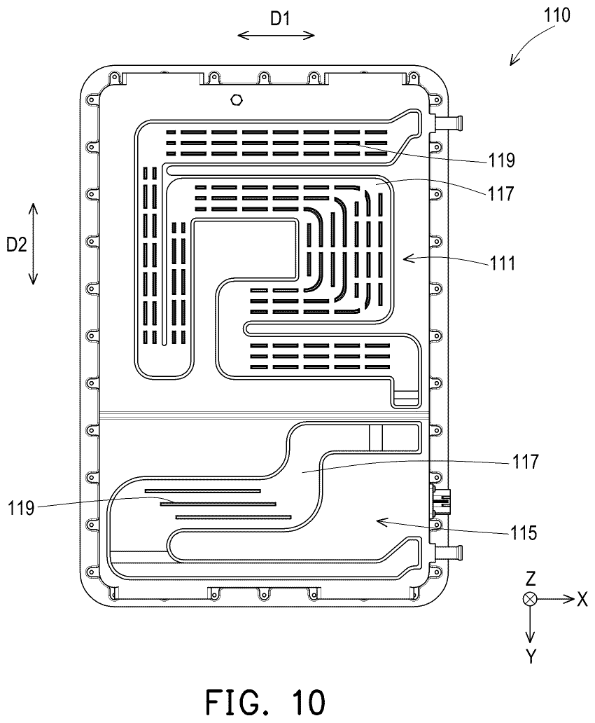

FIG. 10 is a schematic diagram of the heat dissipation casing of FIG. 2 from another viewing angle. In order to clearly illustrate the internal structure of the heat dissipation casing 110, a part of the heat dissipation casing 110 is shown in perspective. Referring to FIG. 10, the heat dissipation casing 110 of the embodiment further includes a liquid cooling pipeline 117. The liquid cooling pipeline 117 extends from the second region 115 to the first region 111, and extending directions D1 and D2 of the liquid cooling pipeline 117 in the first region 111 respectively correspond to extending directions D1 and D2 of the coil 121 as shown in FIG. 2. For example, the extending direction D1 of the upper liquid cooling pipeline 117 shown in FIG. 10 corresponds to the extending direction D1 of the upper left coil 121 shown in FIG. 2. Accordingly, the heat of the coil 121 (FIG. 2) of the embodiment may be effectively dissipated. In the embodiment, the extending direction D1 is parallel to an axial direction X, and the extending direction D2 is parallel to an axial direction Y.

Referring to FIG. 10, the heat dissipation casing 110 further includes fins 119 located in the liquid cooling pipeline 117. The fins 119 have a height extending along an axial direction Z, and extending directions D1 and D2 thereof in the first region 111 respectively correspond to the extending directions D1 and D2 of the coil 121 shown in FIG. 2 and the extending directions D1 and D2 of the liquid cooling pipeline 117 in the first region 111. In the wireless power transmission device 100, the fins 119 are disposed in the liquid cooling pipeline 117 to increase a heat dissipation area, and the wireless power transmission device 100 adjusts a flow rate of a cooling liquid flowing in the liquid cooling pipeline 117 through the fins 119, so that the heat of the coil 121 (FIG. 2) is further effectively dissipated, and the wireless power transmission device 100 may further achieve a good heat dissipation effect.

In the embodiment, the cooling liquid enters from the liquid cooling pipeline 117 of the second region 115 and flows out from the liquid cooling pipeline 117 of the first region 111. When an ambient temperature is 85 degrees, a coolant is water, a coolant temperature is 60 degrees, and a coolant flow rate is 6 LPM, the maximum temperature of the wire 125 is 73.3 degrees, the maximum temperature of the magnetic isolation assembly 123 (FIG. 2) is 76 degrees, and the maximum temperature of the part of the wireless power transmission device 100 that is not heated by the wire 125 (FIG. 2) is 66 degrees. Accordingly, the wireless power transmission device 100 has good heat dissipation effect.

Referring to FIG. 2 and FIG. 3, the wireless power transmission device 100 further includes an outer cover 170. The energy transmission module 120 and the circuit board 160 are located between the outer cover 170 and the heat dissipation casing 110, and the outer cover 170 is fixed to the heat dissipation casing 110 through fasteners F2 (such as screws).

In summary, the wireless power transmission device of the invention includes the heat dissipation casing, the energy transmission module, the first heat dissipation colloid and the second heat dissipation colloid. The wireless power transmission device is sequentially arranged on one side of the coil of the energy transmission module through the first heat dissipation colloid, the magnetic isolation assembly of the energy transmission module, the second heat dissipation colloid, and the heat dissipation casing, so that the heat of the coil may be transmitted to the heat dissipation casing through the first heat dissipation colloid, the magnetic isolation assembly and the second heat dissipation colloid. In this way, the heat of the coil of the wireless power transmission device may be effectively dissipated, and the wireless power transmission device has good heat dissipation effect. In addition, the wireless power transmission device of the invention further includes the blocking structure, the blocking structure may lock the second heat dissipation colloid in the first region, thereby saving the usage amount of the second heat dissipation colloid to save costs. On the other hand, the heat dissipation casing of the wireless power transmission device of the invention further includes the liquid cooling pipeline and fins, so that the heat of the coil may be further effectively dissipated and the wireless power transmission device may further have a good heat dissipation effect.

What is claimed is:

1. A wireless power transmission device, comprising:
a heat dissipation casing;
an energy transmission module, disposed in the heat dissipation casing, and comprising:
a coil; and
a magnetic isolation assembly, disposed between the coil and the heat dissipation casing;
a first heat dissipation colloid, disposed between the coil and the magnetic isolation assembly to make thermocouple of the coil with the magnetic isolation assembly; and
a second heat dissipation colloid, disposed between the magnetic isolation assembly and the heat dissipation casing to make thermocouple of the magnetic isolation assembly with the heat dissipation casing, wherein
heat generated during an operation of the coil is sequentially transmitted to the heat dissipation casing through the first dissipation colloid, the magnetic isolation assembly and the second dissipation colloid.

2. The wireless power transmission device as claimed in claim 1, further comprising a blocking structure, wherein the heat dissipation casing comprises a first region corresponding to the energy transmission module and a retaining wall located next to the first region, the first region comprises a groove, the second heat dissipation colloid is located in the first region and fills a part of the groove, the retaining wall comprises an opening corresponding to the groove, and the blocking structure is disposed in the opening.

3. The wireless power transmission device as claimed in claim 2, wherein the energy transmission module comprises a wire extending from the coil, the blocking structure comprises a notch recessed from an edge, and the wire is located in the groove and extends out of the first region through the notch and the opening.

4. The wireless power transmission device as claimed in claim 3, wherein the blocking structure comprises a first layer structure and a second layer structure attached to the first layer structure, the first layer structure comprises the notch, and the second layer structure comprises a torn region defined by a perforated line, the torn region corresponds to the notch, a strength of the second layer structure is less than a strength of the first layer structure, and the wire passes through the torn region and the notch.

5. The wireless power transmission device as claimed in claim 3, further comprising a circuit board, wherein the heat dissipation casing comprises a second region, the retaining wall is located between the first region and the second region, the circuit board is located in the second region, and the wire extends to the circuit board through the notch and the opening.

6. The wireless power transmission device as claimed in claim 1, wherein the heat dissipation casing comprises a liquid cooling pipeline, the heat dissipation casing comprises a first region corresponding to the energy transmission module, and an extension direction of the liquid cooling pipeline in the first region corresponds to an extending direction of the coil.

7. The wireless power transmission device as claimed in claim 6, wherein the heat dissipation casing comprises a plurality of fins located in the liquid cooling pipeline, and an extending direction of the plurality of fins in the first region corresponds to the extending direction of the coil.

8. The wireless power transmission device as claimed in claim 6, further comprising a circuit board, wherein the heat dissipation casing comprises a second region, the circuit board is located in the second region, and the liquid cooling pipeline extends from the second region to the first region.

9. The wireless power transmission device as claimed in claim 1, wherein the energy transmission module further comprises a coil bracket disposed between the coil and the magnetic isolation assembly, and the coil bracket comprises a through slot with a shape corresponding to the coil, and the first heat dissipation colloid is filled in the through slot.

10. The wireless power transmission device as claimed in claim 1, wherein the energy transmission module further comprises a magnetic isolation assembly bracket disposed between the magnetic isolation assembly and the heat dissipation casing, the magnetic isolation assembly bracket includes comprises a plurality of through holes, and the second heat dissipation colloid is filled in the plurality of through holes.

11. The wireless power transmission device as claimed in claim 1, wherein the energy transmission module comprises an inner cover, the coil and the magnetic isolation assembly are located between the inner cover and the heat dissipation casing, and the inner cover is fixed to the heat dissipation casing to fix the coil and the magnetic isolation assembly in the heat dissipation casing.

12. The wireless power transmission device as claimed in claim 1, further comprising a circuit board and an outer cover, wherein the heat dissipation casing comprises a first region and a second region, the energy transmission module is located in the first region, the circuit board is located in the second region, and the energy transmission module and the circuit board are located between the outer cover and the heat dissipation casing, and the outer cover is fixed to the heat dissipation casing.
